(19) United States
(12) Patent Application Publication
(10) Pub. No.: US 2020/0086280 A1
(43) Pub. Date: Mar. 19, 2020

(54) FILTER ELEMENT AND METHOD OF MANUFACTURING THE SAME

(71) Applicant: National Taiwan University of Science and Technology, Taipei City (TW)

(72) Inventors: Jinn P. CHU, Taipei City (TW); Kassa Shewaye Temesgen, Taipei City (TW); Chien-Chieh HU, Taipei City (TW); Juin-Yih LAI, Taipei City (TW); Chien-Kuang CHEN, Taipei City (TW)

(21) Appl. No.: 16/561,566

(22) Filed: Sep. 5, 2019

Related U.S. Application Data
(60) Provisional application No. 62/733,262, filed on Sep. 19, 2018.

(51) Int. Cl. B01D 69/12; B01D 69/02; B01D 71/02; B01D 71/42; C02F 1/44; B01D 67/00; C23C 14/20; C23C 14/35

(52) U.S. Cl. CPC B01D 69/12; B01D 69/02; B01D 71/022; B01D 71/42; C02F 2101/32; B01D 67/0079; C23C 14/205; C23C 14/35; C02F 1/44

(57) ABSTRACT

A filter element includes a porous membrane and a metallic glass material. The porous membrane is made of a polymer material. The metallic glass material is formed on two opposite surfaces of the porous membrane. The metallic glass material is coated on a plurality of fibrous structures of the porous membrane to improve the strength and the characteristics of the porous membrane.

### CROSS-REFERENCE TO RELATED APPLICATION

This application claims the priority benefits of U.S. provisional application Ser. No. 62/733,262, filed on Sep. 19, 2018, the entirety of which is hereby incorporated by reference herein and made a part of this specification.

### BACKGROUND OF THE INVENTION

### 1. Field of the Invention

The present disclosure generally relates to a filter element, and more particularly to a filter element with a metallic glass material. The present disclosure further comprises a method of manufacturing the filter element.

### 2. Description of the Related Art

Many industries produce enormous volumes of oily wastewater during manufacturing or processing. Since oil can float on water and interfere with the backscattering of light, if the oily wastewater is directly discharged into the environment, it will seriously affect the ecology of aquatic life. Therefore, before the oily wastewater is discharged, it is necessary to perform filtration and purification treatments on the oily wastewater to separate the oil and water as much as possible to reduce the impact of the discharge of the oily wastewater into the environment.

In the traditional wastewater treatment method, surfactants are used to promote the initial separation of oil and water, and then the oil is filtered or absorbed by various physical chemical or biological treatments such that the remaining water can be discharged or recycled. However, remaining water produced by the traditional method can still easily affect the environment. With the advancement of technology, in recent years, some manufacturers have begun to develop membrane filtration technology, which uses membranes having different pore sizes to physically treat oily wastewater. It is more environmentally friendly than traditional wastewater treatment methods. However, in order to meet the wastewater treatment requirements with specific components, these membranes require auxiliary treatments to change their properties, and in the wastewater treatment process, the membranes are susceptible to fouling and chemical degradation, which can reduce the efficiency of wastewater treatment and increase the treatment cost. Therefore, there is a need to provide a filter element with a better filtration effect and better durability.

### SUMMARY OF THE INVENTION

A primary object of this disclosure is to provide a filter element combined with a metallic glass material.

To achieve the aforesaid and other objects, the filter element of this disclosure comprises a porous membrane and a metallic glass material. The porous membrane is made of a polymer material. The metallic glass material is formed on two opposite surfaces of the porous membrane.

In one embodiment of this disclosure, the porous membrane comprises a plurality of fibrous structures, a plurality of pores are formed by the plurality of fibrous structures, and the metallic glass material is coated on the outer surfaces of the plurality of fibrous structures.

In one embodiment of this disclosure, a diameter of each fibrous structure is between 160 nm and 550 nm after the metallic glass material has been coated on the outer surfaces of the plurality of fibrous structures.

In one embodiment of this disclosure, a pore size of each pore ranges from 0.34 μm to 1.56 μm after the metallic glass material has been coated on the outer surfaces of the plurality of fibrous structures.

In one embodiment of this disclosure, a thickness of the metallic glass material ranges from 20 nm to 65 nm.

In one embodiment of this disclosure, a water contact angle of the filter element in atmospheric environment ranges from 100° to 140°.

In one embodiment of this disclosure, the porous membrane is made by an electrospinning process.

In one embodiment of this disclosure, the metallic glass material comprises a zirconium-based metallic glass material.

In one embodiment of this disclosure, the zirconium-based metallic glass material comprises a ZrₐCu_{b}Al_{c}Ni_{d} alloy, wherein a is 55±10 at %, b is 25±5 at %, c is 15±5 at % and d is 1-10 at %, and wherein a, b, c and d independently represent an integer greater than or equal to 1 and a+b+c+d=100.

In one embodiment of this disclosure, the metallic glass material is deposited on the two opposite surfaces of the porous membrane by a radio frequency magnetron sputtering process.

In one embodiment of this disclosure, a weight of the filter element is reduced by 10% to 20% when the filter element is exposed to an ambient temperature of 295° C. to 412° C. as measured by reference to thermogravimetric analysis performed in an ambient temperature range of room temperature to 800° C. at a heating rate of 20° C./min.

In one embodiment of this disclosure, a weight of the filter element is increased by greater than 0% to 1% when the filter element is exposed to an ambient temperature of 412° C. to 514° C. as measured by reference to thermogravimetric analysis performed in an ambient temperature range of room temperature to 800° C. at a heating rate of 20° C./min.

In one embodiment of this disclosure, a weight of the filter element is reduced by 49% to 59% when the filter element is exposed to an ambient temperature of 633° C. to 800° C. as measured by reference to thermogravimetric analysis performed in an ambient temperature range of room temperature to 800° C. at a heating rate of 20° C./min.

In one embodiment of this disclosure, an oil contact angle of the filter element in water is reduced from 111±5° to 0° within a time period.

In one embodiment of this disclosure, an oil retention rate of the filter element to an oil-water mixed solution ranges from 95% to 100% after a surfactant is added to the oil-water mixed solution.

Another object of this disclosure is to provide the method of manufacturing the filter element. The method comprises: providing a porous membrane made of a polymer material, and depositing a metallic glass material on two opposite surfaces of the porous membrane by a radio frequency magnetron sputtering process.

In one embodiment of this disclosure, the porous membrane comprises a plurality of fibrous structures, and the metallic glass material is coated on the outer surfaces of the plurality of fibrous structures.

In one embodiment of this disclosure, during the deposition of the metallic glass material on the porous membrane, the metallic glass material is uniformly coated on the outer surfaces of the plurality of fibrous structures through rotation of the porous membrane.

### BRIEF DESCRIPTION OF THE DRAWINGS

The accompanying drawings are included to provide further understanding of the invention and are incorporated in and constitute a part of this specification. The drawings illustrate embodiments of the invention and, together with the descriptions, serve to explain the principles of the invention.

FIG. 1 illustrates a schematic view of a filter element of this disclosure;

FIG. 2 illustrates a cross-sectional view of a single fibrous structure of the porous membrane of the filter element of this disclosure;

FIG. 3 illustrates a flowchart of a method of manufacturing the filter element of this disclosure;

FIG. 4 illustrates the diameter distributions of the plurality of fibrous structures of the experimental examples B1-B3 and the comparative example A of the filter element of this disclosure;

FIG. 5 illustrates the pore size distributions of the plurality of pores of the experimental example B3 and the comparative example A of the filter element of this disclosure;

FIG. 6 illustrates the water contact angles measured in the atmosphere of the experimental examples B1-B3 and the comparative example A of the filter element of this disclosure;

FIG. 7 illustrates the relationship between the water contact angle, the surface roughness and the thickness of the metallic glass material of the experimental examples B1-B3 and the comparative example A of the filter element of this disclosure;

FIG. 8 illustrates the oil contact angles measured in water of the experimental example B3 and the comparative example A of the filter element of this disclosure; and

FIG. 9 illustrates the thermogravimetric analysis curves of the experimental example B3 and the comparative example A of the filter element of this disclosure.

### DESCRIPTION OF THE EMBODIMENTS

Since the various aspects and embodiments described herein are merely exemplary and not limiting, after reading this specification, skilled artisans will appreciate that other aspects and embodiments are possible without departing from the scope of the disclosure. Other features and benefits of any one or more of the embodiments will be apparent from the following detailed description and the claims.

The use of “a” or “an” is employed to describe elements and components described herein. This is done merely for convenience and to give a general sense of the scope of the invention. Accordingly, this description should be read to include one or at least one and the singular also includes the plural unless it is obvious that it is meant otherwise.

As used herein, the terms “comprises,” “comprising,” “includes,” “including,” “has,” “having” or any other variation thereof are intended to cover a non-exclusive inclusion. For example, a component, structure, article, or apparatus that comprises a list of elements is not necessarily limited to only those elements but may include other elements not expressly listed or inherent to such component, structure, article, or apparatus.

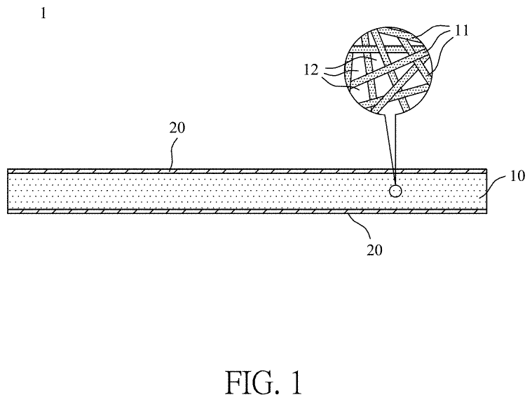

Please refer to FIG. 1, which illustrates a schematic view of a filter element of this disclosure. The filter element 1 of this disclosure can be considered substantially as a layered structure. As illustrated in FIG. 1, the filter element 1 of this disclosure comprises a porous membrane 10 and a metallic glass material 20. The porous membrane 10 is used as a main structural member of the filter element 1 of this disclosure, and the porous membrane 10 is made of a polymer material. In one embodiment of this disclosure, the porous membrane 10 may comprise a nanofiber membrane, such as a polyacrylonitrile (PAN) membrane, which is made by an electrospinning process, but this disclosure is not limited thereto. The porous membrane 10 may also comprise a nanofiber membrane made of another single material or a combination of a plurality of materials of similar strength. Further, the shapes and sizes of the porous membrane 10 can be adjusted according to different use requirements.

The porous membrane 10 made by the electrospinning process comprises a plurality of fibrous structures 11. Since the plurality of fibrous structures 11 are irregularly staggered, a plurality of pores 12 are formed by the plurality of fibrous structures 11, and the plurality of pores 12 have irregular pore sizes.

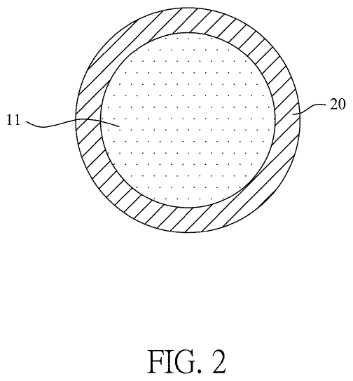

The metallic glass material 20 is substantially formed on two opposite surfaces of the porous membrane 10. In fact, the metallic glass material 20 is coated on the outer surfaces of the plurality of fibrous structures 11 (please refer to FIG. 2). The metallic glass material 20 is mainly used as a structural reinforcement of the filter element 1 of this disclosure to enhance the strength of the porous membrane 10 and to change the characteristics of the filter element 1. Here, the metallic glass material 20 is formed by depositing a metallic glass target on the opposite surfaces of the porous membrane 10 by a radio frequency magnetron sputtering process.

Please refer to FIG. 1 and FIG. 2. FIG. 2 illustrates a cross-sectional view of a single fibrous structure of the porous membrane of the filter element of this disclosure. As illustrated in FIG. 1 and FIG. 2, in one embodiment of this disclosure, the metallic glass material 20 is formed on an outer surface of each of the fibrous structures 11 after the metallic glass material 20 is deposited on the opposite surfaces of the porous membrane 10. In other words, the metallic glass material 20 is uniformly coated on the outer surface of each of the fibrous structures 11. Since the diameter of each of the fibrous structures 11 of the porous membrane 10 is increased after the metallic glass material 20 is deposited, the pore diameter of each of the pores 12 of the porous membrane 10 is reduced. In one embodiment of this disclosure, the thickness of the metallic glass material 20 ranges from 20 nm to 65 nm. Accordingly, after the metallic glass material 20 has been coated on the outer surfaces of the plurality of fibrous structures 11, the diameter of each of the fibrous structures 11 is between 160 nm and 550 nm, and the pore size of each of the pores 12 ranges from 0.34 μm and 1.56 μm, but this disclosure is not limited thereto.

In one embodiment of this disclosure, the metallic glass material 20 may comprise a zirconium-based metallic glass material, but this disclosure is not limited thereto. The metallic glass material 20 may also comprise other metallic glass materials having similar characteristics. Taking a zirconium-based metallic glass material as an example, in one embodiment of this disclosure, the zirconium-based metallic glass material comprises a ZrₐCu_{b}Al_{c}Ni_{d} alloy, wherein a is 55±10 at %, b is 25±5 at %, c is 15±5 at % and d is 1-10 at %, and wherein a, b, c and d independently represent an integer greater than or equal to 1 and a+b+c+d=100.

Here, the metallic glass material 20 has an amorphous structure, in which the atoms are arranged irregularly or without specific order in the structure. The metallic glass material 20 has several satisfactory properties including minimum grain boundary defects, high mechanical strength and toughness, high resistance to corrosion and wear, high antibacterial activity and the ability to provide a smooth hydrophobic surface at room temperature. Accordingly, the filter element 1 of this disclosure can be provided better filtration characteristics by the porous membrane 10 coated with the metallic glass material 20.

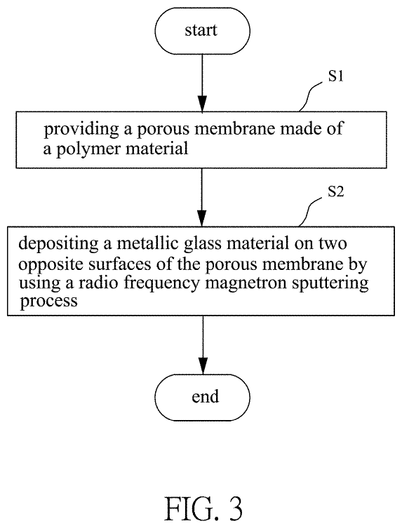

Now refer to FIG. 3, which illustrates a flowchart of a method of manufacturing the filter element of this disclosure. As illustrated in FIG. 3, the method of manufacturing the filter element of this disclosure comprises step S1 and step S2, which are described in detail below.

Step S1: Providing a porous membrane made of a polymer material.

First, a porous membrane 10 suitable for application as a main structural member of the filter element 1 of this disclosure is provided. Here, the porous membrane 10 may be a nanofiber membrane made of a polymer material and having a fixed size and a fixed shape. In the following description, the porous membrane 10 is exemplified by a PAN membrane made by an electrospinning process, but this disclosure is not limited thereto. Since the porous membrane 10 is substantially a sheet structure, two opposite surfaces are formed on two opposite sides of the porous membrane 10. The porous membrane 10 comprises a plurality of fibrous structures 11, and the porous membrane 10 forms a plurality of pores 12 by the plurality of fibrous structures 11 to provide filtering functions.

Step S2: Depositing a metallic glass material on two opposite surfaces of the porous membrane by a radio frequency magnetron sputtering process.

After the porous membrane 10 has been provided in Step S1, a metallic glass material 20 is deposited on two opposite surfaces of the porous membrane 10 by a radio frequency magnetron sputtering process. In one embodiment of this disclosure, a metallic glass target is sputtered by a magnetron sputtering system to deposit the metallic glass material on the two opposite surfaces of the porous membrane 10. In this embodiment, the metallic glass material 20 may be a zirconium-based metallic glass material comprising a ZrₐCu_{b}Al_{c}Ni_{d} alloy. The operating conditions for the radio frequency magnetron sputtering process are a sputtering power of about 100 W, a base pressure of about 6.7×10⁻⁵ Pa and a working pressure of about 3 mTorr, but this disclosure is not limited thereto. The thickness of the deposited metallic glass material 20 can also be changed according to different sputtering times (about 10 to 35 minutes).

During the deposition of the metallic glass material 20 on the porous membrane 10 in Step S2, the metallic glass material 20 may be deposited for substantially equal amounts of time on each of the two opposite surfaces of the porous membrane 10 through rotation of the porous membrane 10 (for example, rotating the porous membrane 10 at a fixed rate or intermittently), such that the metallic glass material 20 is uniformly coated on the outer surfaces of the plurality of fibrous structures 11. Accordingly, each of the fiber structures 11 of the porous membrane 10 is uniformly coated by the metallic glass material 20 as much as possible, as shown in FIG. 2. In one embodiment of this disclosure, the thickness of the deposited metallic glass material 20 ranges from 20 nm to 65 nm.

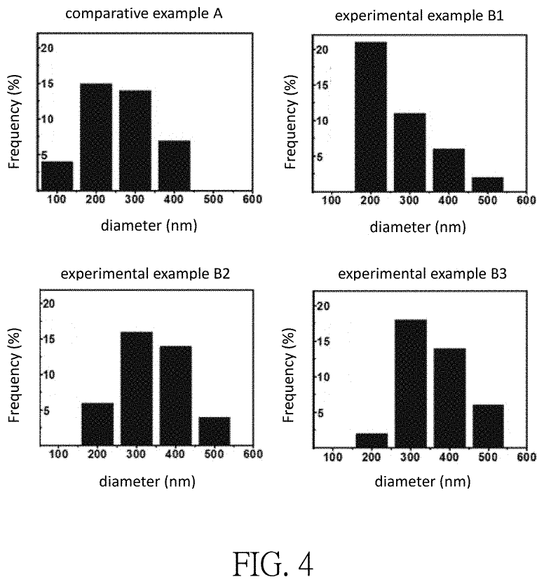

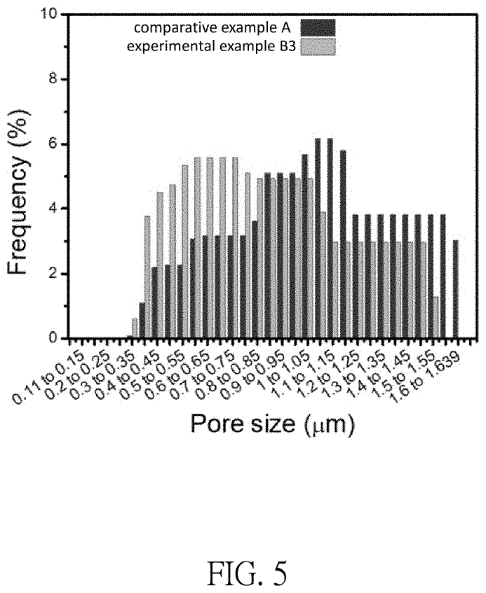

Refer to FIG. 4 and FIG. 5. FIG. 4 illustrates the diameter distributions of the plurality of fibrous structures of the experimental examples B1-B3 and the comparative example A of the filter element of this disclosure; FIG. 5 illustrates the pore size distributions of the plurality of pores of the experimental example B3 and the comparative example A of the filter element of this disclosure. In the following experiments, a porous membrane 10 lacking a coating of the metallic glass material 20 is used as a comparative example A of the filter element. A porous membrane 10 coated with the metallic glass material 20 to a thickness of 24.2 nm is used as an experimental example B1. A porous membrane 10 coated with the metallic glass material 20 to a thickness of 51.0 nm is used as an experimental example B2 of the filter element. A porous membrane 10 coated with the metallic glass material 20 to a thickness of 61.9 nm is used as an experimental example B3 of the filter element. The porous membrane 10 is a PAN membrane having a size of about 4.5 cm×4.5 cm, and the metallic glass material 20 is a zirconium-based metallic glass material comprising a Zr₅₃Cu₂₆Al₁₆Ni₅ alloy.

As illustrated in FIG. 4, according to the statistical experimental data, the average diameter of the plurality of fibrous structures 11 of the porous membrane 10 of the comparative example A is about 236.1 nm, the average diameter of the plurality of fibrous structures 11 of the porous membrane 10 of the experimental example B1 is about 284.2 nm, the average diameter of the plurality of fibrous structures 11 of the porous membrane 10 of the experimental example B2 is about 337.9 nm, and the average diameter of the plurality of fibrous structures 1 of the porous membrane 10 of the experimental example B3 is about 359.8 nm. When the thickness of the metallic glass material 20 deposited on the plurality of fibrous structures of the porous membrane 10 is thicker, the diameter of the plurality of fibrous structures is increased.

In FIG. 5, the comparative example A is compared with the experimental example B3. According to the statistical experimental data, the minimum pore size of the plurality of pores formed by the plurality of fibrous structures of the porous membrane 10 of the comparative example A was about 0.40 μm, and the maximum pore size is about 1.64 μm. The minimum pore size of the plurality of pores formed by the plurality of fibrous structures of the porous membrane 10 of the experimental example B3 was about 0.35 μm, and the maximum pore size was about 1.55 μm. As a whole, when the metallic glass material 20 is deposited on the plurality of fibrous structures of the porous membrane 10, the diameter of the plurality of fibrous structures is increased, but the pore sizes of the plurality of pores formed by the plurality of fibrous structures are relatively reduced. However, it was also found in the experiment that there were no significant differences between the number of the plurality of pores formed in the comparative example A and in the experimental example B3. In other words, even though the pore sizes of the plurality of pores are relatively reduced after the deposition of the metallic glass material 20 on the plurality of fibrous structures of the porous membrane 10, the number of the plurality of pores remains almost unchanged.

The tensile properties of the comparative example A and the experimental examples B1-B3 were tested at room temperature with a Shimadzu EZ-LX 500N test machine at a displacement rate of 5 mm/min. The results are shown in Table 1. As shown in Table 1, the tensile fracture strength and properties of the porous membrane 10 of the experimental examples B1-B3 may be enhanced relative to those of the comparative example A by the deposition of the metallic glass material 20. In particular, under the condition that the thickness of the deposited metallic glass material 20 in the experimental example B3 reaches 61.9 nm, the porous membrane 10 may have a higher tensile fracture strength with no significant loss of tensile strain. Accordingly, the filter element 1 of this disclosure can provide better strength and durability.

TABLE 1

| | Tensile Fracture Strength | Tensile Strain |
|---|---|---|
| | (MPa) | (%) |
| Comparative example A | 0.019 | 20.50 |
| Experimental example B1 | 0.021 | 7.43 |
| Experimental example B2 | 0.912 | 6.67 |
| Experimental example B3 | 0.252 | 20.47 |

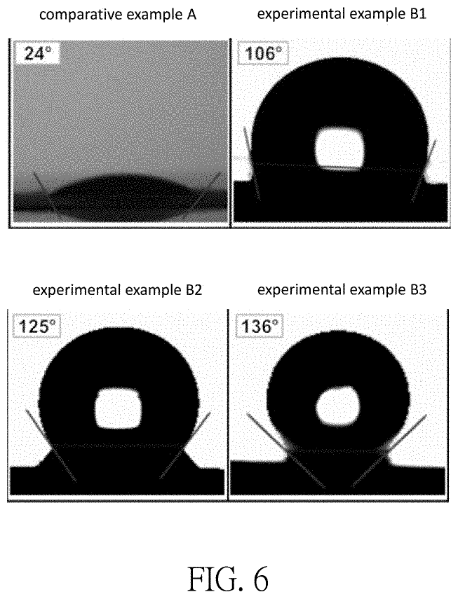

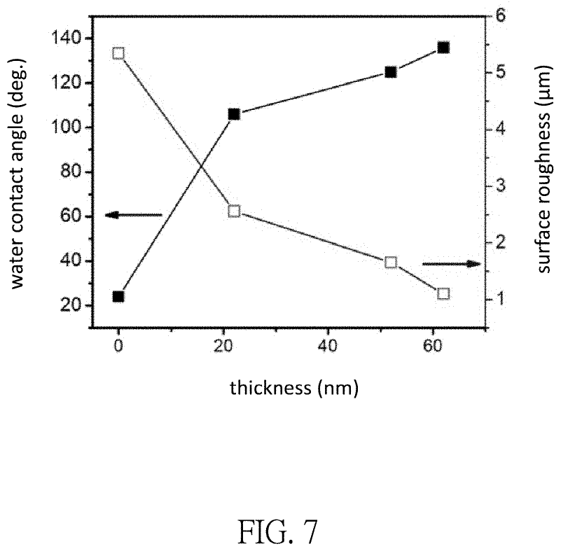

Refer to FIG. 6 and FIG. 7. FIG. 6 illustrates the water contact angles measured in the atmosphere of the experimental examples B1-B3 and the comparative example A of the filter element of this disclosure; FIG. 7 illustrates the relationship between the water contact angle, the surface roughness and the thickness of the metallic glass material of the experimental examples B1-B3 and the comparative example A of the filter element of this disclosure. In the following experiments, the comparative example A and the experimental examples B1-B3 were placed in an atmospheric environment. After water droplets were dropped onto the surface of the filter element of the comparative example A and the experimental examples B1-B3 respectively, the water contact angles exhibited by the water droplets at room temperature were measured by an automatic interfacial tensiometer. As shown in FIG. 6, the water contact angle of the filter element of the comparative example A was about 24°, indicating that the filter element comprising only the PAN membrane exhibited high hydrophilicity. In contrast, the water contact angle of the filter element of the experimental example B1 was about 106°, the water contact angle of the filter element of the experimental example B2 was about 125°, and the water contact angle of the filter element of the experimental example B3 was about 136°. The water contact angle of any of the experimental examples B1-B3 was obviously greater than the water contact angle of the comparative example A. Accordingly, when the thickness of the metallic glass material deposited on the outer surface of the PAN membrane ranges from about 20 nm to 65 nm, the water contact angle measured in the atmosphere ranges from about 100° to 140°, exhibiting a stable high level of hydrophobicity.

As illustrated in FIG. 7, the water contact angle of the filter element of this disclosure may be increased when the thickness of the metallic glass material is increased. In order to increase the thickness of the metallic glass material, the time for which the radio frequency magnetron sputtering process of the porous membrane of the filter element of this disclosure is performed must be increased. Increasing the thickness of the metallic glass material will improve the uniformity of the metallic glass material deposited on the porous membrane, thereby reducing the surface roughness of the filter element of this disclosure. Accordingly, the surface roughness of the filter element of this disclosure may be decreased when the thickness of the metallic glass material is increased.

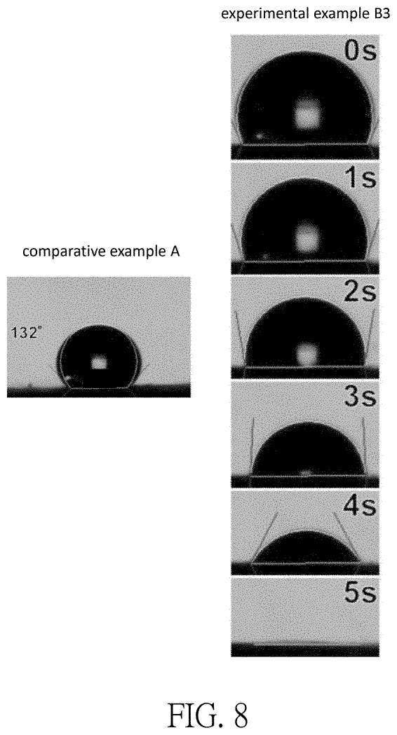

Refer to FIG. 8, which illustrates the oil contact angles measured in water of the experimental example B3 and the comparative example A of the filter element of this disclosure. In the following experiments, the comparative example A and the experimental examples B1-B3 were placed in an aqueous environment. After oil droplets were dropped onto the surface of the filter element of the comparative example A and the experimental example B3 respectively, the oil contact angles exhibited by the oil droplets at room temperature were measured with an automatic interfacial tensiometer. As shown in FIG. 8, the oil contact angle of the filter element of the comparative example A was about 132°, indicating that the filter element comprising only the PAN membrane exhibited high underwater oleophobicity. However, the oil contact angle of the filter element of the experimental example B3 in water was about 111±5° at the beginning, and then the oil contact angle gradually decreased to 0° within a time period (for example, in this embodiment, about 5 seconds). Accordingly, when the metallic glass material was deposited on the outer surface of the PAN membrane of the filter element of this disclosure, the oil contact angle measured in water was reduced from 111±5° to 0° within a time period; therefore, the filter element of the experimental example B3 exhibited high underwater lipophilicity.

As described above, the filter element of this disclosure substantially allows oil to pass through it and hinders the penetration of water to achieve the effect of oil-water separation. In addition, the selectivity for liquids and flux of the filter element of this disclosure may be changed by the use of surfactants. In the following experiments employing the comparative example A and experimental example B3, sodium dodecyl sulfate (SDS) was added to the oil-water mixed solution as a surfactant to form an oil-water emulsion, and the oil droplet size distributions and the oil-water separation effects in the oil-water emulsion were observed by dynamic light scattering (DLS; Nano-Zs90) and an optical microscope (OM; Nikon Japan, FN-S2N). The results are shown in Table 2. As shown in Table 2, when the concentration of the added surfactant was about 0.8 mg/300 ml, the particle dispersed size of the oil-water emulsion was about 861 nm, and the filter element of the experimental example B3 provided water flux of only 11.6 L/m²h to yield a retention rate of up to 100%. The calculation formula of the retention rate is as follows:

R(%)=(1−(Cₚ/C_{f}))×100%

where R is the retention rate, Cₚ is the oil concentration in the permeate, and C_{f} is the oil concentration in the feed.

Since SDS is a highly hydrophilic surfactant, the metallic glass material of the experimental example B3 was connected with the hydrophobic portion of the SDS, and the hydrophilic portion of the SDS was outwardly exposed, which in turn caused the water contact angle of the experimental example B3 to decrease. Therefore, water could easily pass through the filter element and produce the oil resistance effect. When the concentration of the surfactant added was about 51 mg/300 ml, the particle dispersed size of the oil-water emulsion was reduced to about 243 nm. At this time, the water flux of the filter element of the experimental example B3 was increased to 814 L/m²h. but it still maintained a retention rate of 95%, which was more significant than that of the comparative example A under the same conditions. Accordingly, the oil retention rate of the filter element of this disclosure ranged from 95% to 100% under the aforementioned experimental conditions.

TABLE 2

| | | | Retention | |
|---|---|---|---|---|
| | SDS | PDS | rate | Flux |
| | Concentration | (nm) | (%) | (L/m²h) |
| Experimental | 0.8 mg/300 ml | 861 | 100 | 11.6 |
| example B3 | | | | |
| Comparative | | | 98 | 371 |
| example A | | | | |
| Experimental | 51 mg/300 ml | 243 | 95 | 814 |
| example B3 | | | | |
| Comparative | | | 70 | 4159 |
| example A | | | | |

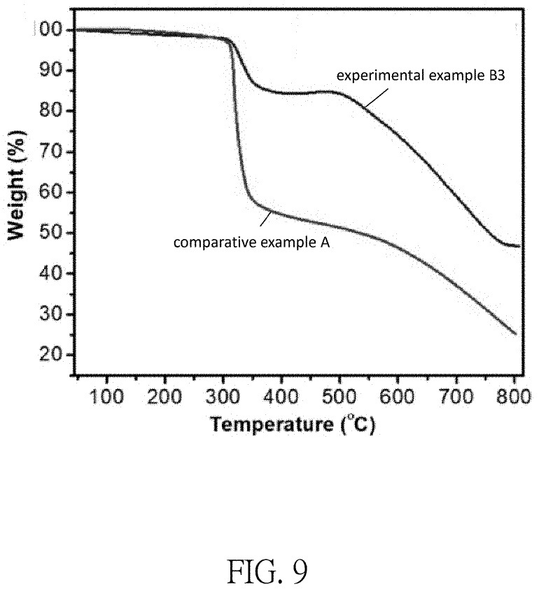

Refer to FIG. 9, which illustrates the thermogravimetric analysis curves of the experimental example B3 and the comparative example A of the filter element of this disclosure. In the following experiment, the filter elements of the comparative example A and experimental example B3 were placed in a nitrogen atmosphere at a flow rate of 20 ml/min, and the ambient temperature was raised from room temperature to 800° C. at a heating rate of 20° C./min so as to facilitate thermogravimetric analysis (TGA) under the foregoing conditions. As shown in FIG. 9, before the ambient temperature was raised to about 295° C., the weights of the filter elements of the comparative example A and the experimental example B3 were only slightly reduced by about 5%. When the ambient temperature was raised to about 295° C., a pyrolysis reaction began to cause a significant loss of weight of the PAN membrane. When the ambient temperature was raised from about 295° C. to about 412° C., the weight of the filter element of the experimental example B3 was reduced by about 10% to 20%, and the weight of the filter element of the comparative example A was reduced by about 40% to 50% under the same temperature condition. When the ambient temperature was raised from about 412° C. to about 514° C., the weight of the filter element of the experimental example B3 began increase by greater than 0% to 1%, and the weight of the filter element of the comparative example A continued to decrease by about 50% under the same temperature condition. When the ambient temperature was raised from about 633° C. to about 800° C., the weight of the filter element of the experimental example B3 was reduced by about 49% to 59%, and the weight of the filter element of the comparative example A was reduced by about 70% to 80% under the same temperature condition. Accordingly, the pyrolysis reaction of the PAN membrane of the filter element of the experimental example B3 was effectively suppressed relative to the pyrolysis reaction of the PAN membrane of the filter element of the comparative example A, and thus the thermal stability was higher.

In summary, the original hydrophilic and hydrophobic properties of the porous membrane 10 of the filter element 1 of this disclosure can be changed by depositing the metallic glass material 20 on the outer surfaces of the plurality of fiber structures of the porous membrane 10, and a better oil-water separation effect of the filter element 1 of this disclosure can be provided by the use of a surfactant. In addition, the deposited metallic glass material 20 can improve the thermal stability, chemical stability, structural strength and toughness of the porous membrane 10.

The above detailed description is merely illustrative in nature and is not intended to limit the embodiments of the subject matter or the application and uses of such embodiments. Moreover, while at least one exemplary embodiment has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description will provide those skilled in the art with a convenient guide for implementing the described one or more embodiments. Also, various changes can be made to the function and arrangement of elements without departing from the scope defined by the claims, which include known equivalents and foreseeable equivalents at the time of filing of this patent application.

What is claimed is:

1. A filter element, comprising:
a porous membrane made of a polymer material; and
a metallic glass material formed on two opposite surfaces of the porous membrane.

2. The filter element of claim 1, wherein the porous membrane comprises a plurality of fibrous structures, a plurality of pores are formed by the plurality of fibrous structures, and the metallic glass material is coated on the outer surfaces of the plurality of fibrous structures.

3. The filter element of claim 2, wherein a diameter of each fibrous structure is between 160 nm and 550 nm after the metallic glass material has been coated on the outer surfaces of the plurality of fibrous structures.

4. The filter element of claim 3, wherein a pore size of each pore ranges from 0.34 μm to 1.56 μm after the metallic glass material has been coated on the outer surfaces of the plurality of fibrous structures.

5. The filter element of claim 2, wherein a thickness of the metallic glass material ranges from 20 nm to 65 nm.

6. The filter element of claim 5, wherein a water contact angle of the filter element in atmospheric environment ranges from 100° to 140°.

7. The filter element of claim 2, wherein the porous membrane is made by an electrospinning process.

8. The filter element of claim 1, wherein the metallic glass material comprises a zirconium-based metallic glass material.

9. The filter element of claim 8, wherein the zirconium-based metallic glass material comprises a ZrₐCu_{b}Al_{c}Ni_{d} alloy, wherein a is 55±10 at %/o, b is 25±5 at %/o, c is 15±5 at % and d is 1-10 at %, and wherein a, b, c and d independently represent an integer greater than or equal to 1 and a+b+c+d=100.

10. The filter element of claim 1, wherein the metallic glass material is deposited on the two opposite surfaces of the porous membrane by a radio frequency magnetron sputtering process.

11. The filter element of claim 1, wherein a weight of the filter element is reduced by 10% to 20% when the filter element is exposed to an ambient temperature of 295° C. to 412° C. as measured by reference to thermogravimetric analysis performed in an ambient temperature range of room temperature to 800° C. at a heating rate of 20° C./min.

12. The filter element of claim 1, wherein a weight of the filter element is increased by greater than 0% to 1% when the filter element is exposed to an ambient temperature of 412° C. to 514° C. as measured by reference to thermogravimetric analysis performed in an ambient temperature range of room temperature to 800° C. at a heating rate of 20° C./min.

13. The filter element of claim 1, wherein a weight of the filter element is reduced by 49% to 59% when the filter element is exposed to an ambient temperature of 633° C. to 800° C. as measured by reference to thermogravimetric analysis performed in an ambient temperature range of room temperature to 800° C. at a heating rate of 20° C./min.

14. The filter element of claim 1, wherein an oil contact angle of the filter element in water is reduced from 111±5° to 0° within a time period.

15. The filter element of claim 1, wherein an oil retention rate of the filter element for an oil-water mixed solution ranges from 95% to 100% after a surfactant is added to the oil-water mixed solution.

16. A method of manufacturing the filter element as recited in claim 1, comprising:
providing a porous membrane made of a polymer material; and
depositing a metallic glass material on two opposite surfaces of the porous membrane by a radio frequency magnetron sputtering process.

17. The method of claim 16, wherein the porous membrane comprises a plurality of fibrous structures, and the metallic glass material is coated on the outer surfaces of the plurality of fibrous structures.

18. The method of claim 17, wherein during the deposition of the metallic glass material on the porous membrane, the metallic glass material is uniformly coated on the outer surfaces of the plurality of fibrous structures through rotation of the porous membrane.
